(19) United States
(12) Patent Application Publication
(10) Pub. No.: US 2025/0101579 A1
(43) Pub. Date: Mar. 27, 2025

(54) METHODS FOR FORMING A DOPED HAFNIUM ZIRCONIUM OXIDE LAYER ON A SUBSTRATE

(71) Applicant: ASM IP Holding B. V., Almere (NL)

(72) Inventors: Alessandra Leonhardt, Sipoo (FI); Matthew Surman, Helsinki (FI); Rohit Abraham John, Chandler, AZ (US); Fu Tang, Gilbert, AZ (US); Andrea llliberi, Leuven (BE); Vivek Koladi Mootheri, Leuven (BE); Leo Lukose, Leuven (BE); Varun Sharma, Helsinki (FI); Jessica Akemi Cimada da Silva, Chandler, AZ (US)

(21) Appl. No.: 18/898,409

(22) Filed: Sep. 26, 2024

Related U.S. Application Data
(60) Provisional application No. 63/585,812, filed on Sep. 27, 2023.

(51) Int. Cl. C23C 16/40; C23C 16/02; C23C 16/44; C23C 16/455

(52) U.S. Cl. CPC C23C 16/405; C23C 16/0281; C23C 16/4408; C23C 16/45553; H10D 1/68

(57) ABSTRACT

The technology of the present disclosure generally relates to the field of capacitor devices. More particularly to Metal-Insulator-Metal capacitors (MIM CAPS) comprising a Hafnium Zirconium Oxide (HZO) layer, and a method for producing the same. Further described are related methods, deposition systems, and devices. The method for forming the doped HZO layer on a substrate, comprises the steps of providing a substrate in a reaction chamber; executing one or more cycles whereby each cycle comprising contacting a hafnium precursor, a zirconium precursor, an oxygen reactant and a dopant precursor on at least part of the substrate by introducing the precursors and reactant in the reaction chamber; the dopant precursor comprises a dopant element having three or four valence electrons and an atomic radius which is less than the atomic radius of an Hf or Zr element of the HZO layer.

### CROSS-REFERENCE TO RELATED APPLICATION(S)

This Application claims the benefit of U.S. Provisional Application 63/585,812 filed on Sep. 27, 2023, the entire contents of which are incorporated herein by reference.

### FIELD OF INVENTION

The present disclosure generally relates to the field of capacitor devices. More particularly, to Metal-Insulator-Metal capacitors (MIM CAPS) comprising a Hafnium Zirconium Oxide (HZO) layer, and a method for producing the same.

### BACKGROUND OF THE DISCLOSURE

Capacitors are electronic components that are used to store and regulate electrical energy in an electrical field by accumulating electric charges on two closely spaced surfaces which are insulated from each other. Typically, a capacitor is a component widely used as parts of electrical circuits in many common electrical devices and are designed with specific capacitance values and voltage ratings to suit the requirements of various applications. Most capacitors contain at least two electrical conductors which serve as the electrodes of the capacitor and are separated by an insulating layer. These structures are also referred to as Metal-Insulator-Metal capacitors (MIM CAPS). The nonconducting insulator or dielectric acts to increase the capacitor's charge capacity. An ideal capacitor is characterized by a constant capacitance C. The capacitance between the two conductors is a function of the geometry or surface area of the conductors and the distance between the two conductors, and the permittivity of the isolating material between them. In a capacitor, the highest capacitance is achieved with a high permittivity dielectric material, large plate area and a small separation between the plates. The relative permittivity is an essential parameter when designing capacitors. If a material with a high relative permittivity is placed in an electric field, the magnitude of that field will be measurably reduced within the volume of the dielectric. This fact is commonly used to increase the capacitance of a particular capacitor design.

Next generation MIM CAPS for both logic and memory applications desire a very high dielectric constant value κ, while having a linear Capacitance Voltage (CV) characteristic. A high dielectric constant value and high capacitance density can be achieved by using a ferroelectric/antiferroelectric Hafnium Zirconium Oxide (HZO) layer resulting in a dielectric constant value κ above 40 and experiencing low leakage. However, such capacitors have the problem that the CV characteristic is non-linear and results in a peak of the dielectric constant value κ around 0V, while the dielectric constant value κ at other desired fields may be significantly lower. Also, such material having a non-linear CV characteristic have proven to be difficult when integrating them in devices or circuits. Therefore, there is a need to develop alternative materials having a linear CV characteristics and a peak of the dielectric constant value x in a desired field.

### SUMMARY OF THE DISCLOSURE

This summary is provided to introduce a selection of concepts in a simplified form. These concepts are described in further detail in the detailed description of example embodiments of the disclosure below. This summary is not intended to identify key features or essential features of the claimed subject matter, nor is it intended to be used to limit the scope of the claimed subject matter. An aspect of the present disclosure relates to a method for forming a doped hafnium zirconium oxide (HZO) layer on a substrate, the method comprising the steps of:
a) providing said substrate in a reaction chamber;
b) executing one or more cycles, a cycle comprising
   i. a hafnium precursor pulse, wherein at least a part of the substrate is contacted with one or more hafnium precursor by introducing said one or more hafnium precursor in the reaction chamber;
   ii. a zirconium precursor pulse, wherein at least a part of the substrate is contacted with one or more zirconium precursor by introducing said one or more zirconium precursor in the reaction chamber;
   iii. an oxygen reactant pulse, wherein at least a part of the substrate is contacted with one or more oxygen reactant by introducing said one or more oxygen reactant in the reaction chamber; and
   iv. a dopant precursor pulse, wherein at least a part of the substrate is contacted with one or more dopant precursor by introducing said one or more dopant precursor in the reaction chamber,
      thereby forming a doped HZO layer;
         wherein said dopant precursor comprises a dopant element characterized by having three or four valence electrons and an atomic radius which is less than the atomic radius of an Hf or Zr element of the HZO layer.

In a particular embodiment, the method as disclosed herein provides that an oxygen reactant pulse is carried out after each hafnium precursor pulse and/or after each zirconium precursor pulse.

In a particular embodiment, the method as disclosed herein provides that the dopant precursor pulse is carried out after said hafnium precursor pulse without any intervening oxygen reactant pulse.

In a particular embodiment, the method as disclosed herein provides that the dopant precursor pulse is carried out after said zirconium precursor pulse without any intervening oxygen reactant pulse.

In a particular embodiment, the method as disclosed herein provides that each pulse is followed by a purge with an inert gas chosen from at least one of N₂ and a noble gas.

In a particular embodiment, the method as disclosed herein provides that the hafnium precursor pulse, the zirconium precursor pulse, the oxygen reactant pulse and/or the dopant precursor pulse comprises a plurality of micropulses.

In a particular embodiment, the method as disclosed herein provides that the dopant element is selected from the list consisting of Aluminium (Al), Silicon (Si), Nickel (Ni), Germanium (Ge), Gallium (Ga) and Carbon (C).

In a particular embodiment, the method as disclosed herein provides that the concentration of said dopant element in said HZO layer ranges between 0.50 and 8.0% of the relative dopant element concentration, more particularly between 1.0 and 5.0% of the relative dopant element concentration, and even more particularly between 2.0 and 4.50% of the relative dopant element concentration.

In a particular embodiment, the dopant element used in the method is Al. In particular, the dopant precursor is a low-reactivity precursor, said dopant precursor preferably being a low-reactivity Aluminium precursor represented by the general formula Al(R¹)₃, wherein each R¹ is independently selected from the group consisting of hydrogen, halogen, alkyl, alkenyl, N(R²)₂, cycloalkyl, and alkoxy, and wherein each R² is chosen from hydrogen, alkyl, or alkenyl. In particular, wherein each R¹ is independently selected from the group consisting of hydrogen, halogen, C₁₋₈alkyl, C₂₋₈alkenyl, C₃₋₈cycloalkyl, and C₁₋₈alkoxy, and wherein each R² is chosen from hydrogen, C₁₋₈alkyl, or C₂₋₈alkenyl. In particular, wherein said Aluminium precursor is selected from the list consisting of aluminum hydride (AlH₃), aluminum trifluoride (AlF₃), aluminum trichloride (AiCl₃), aluminum tribromide (AlBr₃), aluminum triiodide (AlI₃), trimethylaluminum (Al(CH₃)₃), triethylaluminum (Al(C₂H₅)₃, tri(isopropyl)aluminum (Al(ⁱPr)₃), tetra-n-butylaluminum (Al(C₄H₉)₃), tetra-t-butylaluminum (Al(O^{t}Bu)₃), aluminum methoxide (Al(OCH₃)₃), aluminum ethoxide (Al(OC₂H₅)₃), aluminum isopropoxide (Al(OⁱPr)₃), aluminum n-butoxide (Al(OC₄H₉)₃), and aluminum t-butoxide (Al(O^{t}Bu)₃).

In a particular embodiment, the dopant element used in the method is Si. In particular, the dopant precursor is a low-reactivity precursor, said dopant precursor preferably being a low-reactivity Silicon precursor selected from the list consisting of silicon tetraacetate (Si(OOCCH₃)₄), and Si(R³)₄, wherein each R³ is independently selected from the group consisting of hydrogen, halogen, alkyl, alkenyl, N(R⁴)₂, cycloalkyl, and alkoxy, and wherein each R⁴ is chosen from hydrogen, alkyl, or alkenyl. In particular, wherein each R³ is independently selected from the group consisting of hydrogen, halogen, C₁₋₈alkyl, C₂₋₈alkenyl, C₃₋₈cycloalkyl, and C₁₋₈alkoxy, and wherein each R⁴ is chosen from hydrogen, C₁₋₈alkyl, or C₂₋₈alkenyl. In particular, wherein said silicon precursor is selected from the list consisting of silane (SiH₄), silicon tetrafluoride (SiF₄), silicon tetrachloride (SiCl₄), silicon tetrabromide (SiBr₄), silicon tetraiodide (SiI₄), tetramethylsilane (Si(CH₃)₄), tetraethylsilane (Si(C₂H₅)₄, tetra(isopropyl)silane (Si(ⁱPr)₄), tetra-n-butylsilane (Si(C₄H₉)₄), tetra-t-butylsilane (Si(OₜBu)₄), tetramethoxysilane (Si(OCH₃)₄), tetraethoxysilane (Si(OC₂H₅)₄), tetra(isopropoxy)silane (Si(OⁱPr)₄), tetra-n-butoxysilane (Si(OC₄H₉)₄), tetra-t-butoxysilane (Si(O^{t}Bu)₄), and tris(dimethylamino)silane (Si(N[CH₃]₂)₃).

In a particular embodiment, the dopant element used in the method is Ge. In particular, the dopant precursor is a low-reactivity precursor, said dopant precursor preferably being a low-reactivity Germanium precursor represented by the general formula Ge(R⁵)₄, wherein each R⁵ is independently selected from the group consisting of hydrogen, halogen, alkyl, alkenyl, N(R⁶)₂, cycloalkyl, and alkoxy, and wherein each R⁶ is chosen from hydrogen, alkyl, or alkenyl. In particular, wherein each R⁵ is independently selected from the group consisting of hydrogen, halogen, C₁₋₈alkyl, C₂₋₈alkenyl, C₃₋₈cycloalkyl, and C₁₋₈alkoxy, and wherein each R⁶ is chosen from hydrogen, C₁₋₈alkyl, or C₂₋₈alkenyl. In particular, wherein said Germanium precursor is selected from the list consisting of germane (GeH₄), germanium tetrafluoride (GeF₄), germanium tetrachloride (GeCl₄), germanium tetrabromide (GeBr₄), germanium tetraiodide (GeI₄), tetramethylgermanium (Ge(CH₃)₄), tetraethylgermanium (Ge(C₂H₅)₄, tetra(isopropyl)germanium (Ge(ⁱPr)₄), tetra-n-butylgermanium (Ge(C₄H₉)₄), tetra-t-butylgermanium (Ge(OₜBu)₄), tetramethoxygermanium (Ge(OCH₃)₄), tetraethoxygermanium (Ge(OC₂H₅)₄), tetra(isopropoxy)germanium (Ge(OC₃H₇)₄), tetra-n-butoxygermanium (Ge(OC₄H₉)₄), tetra-t-butoxygermanium (Ge(O^{t}Bu)₄), and tetrakis(dimethylamino)germanium (Ge(N[CH₃]₂)₄).

In a particular embodiment, the method as disclosed herein provides that the hafnium precursor is chosen from the list consisting of HfCl₄, HfBr₄, HfI₄, Tetrakis(dimethylamido)hafnium (Hf(N(CH₃)₂)₄), Tetrakis(ethylmethylamino)hafnium (Hf(N(C₂H₅)(CH₃))₄), Tetrakis(diethylamido)hafnium (Hf(N(C₂H₅)₂)₄), Hf(OR)₄, Tris(dimethylamino)cyclopentadienyl Hafnium (HfCp(NMe₂)₃), Hf(CpMe)₂[OMe]Me, Hf(CpMe)₂Me₂, and Tetrakis(1-methoxy-2-methyl-2-propoxy)hafnium (Hf(mmp)₄).

In a particular embodiment, the method as disclosed herein provides that the zirconium precursor is chosen from the list consisting of tetrakis(dimethylamino)zirconium, tetrakis(diethylamino)zirconium, and tetrakis(ethylmethylamino)zirconium, and Tris(dimethylamino)cyclopentadienyl Zirconium.

In some embodiments, the method as disclosed herein provides that the decomposition temperature of the dopant precursor is higher compared to the operating temperature to form the doped hafnium zirconium oxide (HZO) layer.

In some embodiments, the method as disclosed herein provides that the operating temperature to form the doped HZO layer is between 150° C. and 450° C., preferably between 250° C. and 350° C., more preferably around 300° C.

In some embodiments, the method as disclosed herein is an Atomic Layer Deposition (ALD) method.

In some embodiments, the method as disclosed herein further comprising the step of providing a seed layer prior to forming said doped HZO layer, said seed layer being a ZrO₂ seed layer. Preferably, the substrate comprises a Metal Oxide (MO) surface layer, and/or wherein said method further comprises the step of forming a Metal Oxide (MO) top layer on said doped HZO layer, thereby forming a layered doped HZO structure. Furthermore, the MO surface layer and/or the MO top layer is in direct contact with the doped HZO layer. Preferably, the metal oxide is TiO₂.

In some embodiments, the method as disclosed herein provides that the doped HZO layer stabilises the tetragonal phase of said HZO layer such that a Morphotropic Phase Boundary (MPB) is reached between the orthorhombic and tetragonal phases of said HZO layer to allow a change in the polarisation switching voltage of said HZO layer.

In some embodiments, the method as disclosed herein provides that changing the polarisation switching voltage of the HZO layer changes the Capacitance Voltage (CV) linearity of the HZO layer.

In some embodiments, the method as disclosed herein provides that the doped HZO layer increases the dielectric constant value (κ) of the HZO layer.

In some embodiments, the method as disclosed herein provides that the dielectric constant value (κ) of the doped HZO layer is above 35, preferably above 45 at about −2 and −3 MV/cm.

In some embodiments, the method as disclosed herein provides that the doped HZO layer is formed without any intervening vacuum break.

In a particular embodiment, a doped hafnium zirconium oxide (HZO) layer is obtained by a method as disclosed herein.

In a particular embodiment, a layered doped HZO structure is obtained by a method as disclosed herein.

In a particular embodiment, a doped hafnium zirconium oxide (HZO) layer is obtained by a method as disclosed herein as an insulator in a metal-insulator-metal capacitor (MIM CAPS).

These and other embodiments will become readily apparent to those skilled in the art from the following detailed description of certain embodiments having reference to the attached figures; the invention not necessarily being limited to any particular embodiment(s) disclosed.

### BRIEF DESCRIPTION OF THE FIGURES

A more complete understanding of exemplary embodiments of the present disclosure can be derived by referring to the detailed description and claims when considered in connection with the following illustrative figures.

FIG. 1 describes an exemplary embodiment of a method for forming a doped hafnium zirconium oxide (HZO) layer on a substrate.

FIG. 2a illustrates a first modification to a CV curve by doping the HZO layer according to the disclosure, FIG. 2b illustrates a second modification to a CV curve by doping the HZO layer according to the disclosure, and FIG. 2c illustrates a third modification to a CV curve by doping the HZO layer according to the disclosure.

FIG. 3 schematically shows an exemplary MIM capacitor (300) of the disclosure.

FIG. 4 schematically illustrates another exemplary MIM capacitor (400) of the disclosure.

FIG. 5 schematically illustrates a further exemplary MIM capacitor (500) of the disclosure.

FIG. 6 schematically illustrates a system (600) in accordance with yet additional exemplary embodiments of the disclosure.

It will be appreciated that elements in the figures are illustrated for simplicity and clarity and have not necessarily been drawn to scale. For example, the dimensions of some of the elements in the figures may be exaggerated relative to other elements to help improve understanding of illustrated embodiments of the present disclosure.

### DETAILED DESCRIPTION OF EXEMPLARY EMBODIMENTS

Although certain embodiments and examples are disclosed below, it will be understood by those in the art that the present disclosure extends beyond the specifically disclosed embodiments and/or uses of the present disclosure and obvious modifications and equivalents thereof. Thus, it is intended that the scope of the present disclosure disclosed should not be limited by the particular disclosed embodiments described below.

In the following detailed description, the technology underlying the present disclosure will be described by means of different aspects thereof. It will be readily understood that the aspects of the present disclosure, as generally described herein, and illustrated in the figures, can be arranged, substituted, combined, and designed in a wide variety of different configurations, all of which are explicitly contemplated and make part of this disclosure. This description is meant to aid the reader in understanding the technological concepts more easily, but it is not meant to limit the scope of the present disclosure, which is limited only by the claims.

Reference throughout this specification to “one embodiment” or “an embodiment” means that a particular feature, structure or characteristic described in connection with the embodiment is included in at least one embodiment of the present disclosure. Thus, appearances of the phrases “in one embodiment” or “in an embodiment” in various places throughout this specification are not necessarily all referring to the same embodiment.

As used herein, the terms “comprising”, “comprises” and “comprised of” as used herein are synonymous with “including”, “includes” or “containing”, “contains”, and are inclusive or open-ended and do not exclude additional, non-recited members, elements or method steps. The terms “comprising”, “comprises” and “comprised of” when referring to recited members, elements or method steps also include embodiments which “consist of” the recited members, elements or method steps. The singular forms “a”, “an”, and “the” include both singular and plural referents unless the context clearly dictates otherwise.

Objects described herein as being “connected” or “coupled” reflect a functional relationship between the described objects, that is, the terms indicate the described objects must be connected in a way to perform a designated function which may be a direct or indirect connection in an electrical or nonelectrical (i.e. physical) manner, as appropriate for the context in which the term is used.

As used herein, the term “substantially” refers to the complete or nearly complete extent or degree of an action, characteristic, property, state, structure, item, or result. For example, an object that is “substantially” enclosed would mean that the object is either completely enclosed or nearly completely enclosed. The exact allowable degree of deviation from absolute completeness may in some cases depend on the specific context. However, generally speaking the nearness of completion will be so as to have the same overall result as if absolute and total completion were obtained. The use of “substantially” is equally applicable when used in a negative connotation to refer to the complete or near complete lack of an action, characteristic, property, state, structure, item, or result.

As used herein, the term “about” is used to provide flexibility to a numerical value or range endpoint by providing that a given value may be “a little above” or “a little below” the value or endpoint, depending on the specific context. Unless otherwise stated, use of the term “about” in accordance with a specific number or numerical range should also be understood to provide support for such numerical terms or range without the term “about”. For example, the recitation of “about 30” should be construed as not only providing support for values a little above and a little below 30, but also for the actual numerical value of 30 as well.

The recitation of numerical ranges by endpoints includes all integer numbers and, where appropriate, fractions subsumed within that range (e.g., 1 to 5 can include 1, 2, 3, 4 when referring to, for example, a number of elements, and can also include 1.5, 2, 2.75 and 3.80, when referring to, for example, measurements). The recitation of end points also includes the end point values themselves (e.g., from 1.0 to 5.0 includes both 1.0 and 5.0). Any numerical range recited herein is intended to include all sub-ranges subsumed therein. Furthermore, the terms first, second, third and the like in the description and in the claims, are used for distinguishing between similar elements and not necessarily for describing a sequential or chronological order, unless specified. It is to be understood that the terms so used are interchangeable under appropriate circumstances and that the embodiments of the disclosure described herein are capable of operation in other sequences than described or illustrated herein.

Reference in this specification may be made to devices, structures, systems, or methods that provide “improved” performance (e.g. increased or decreased results, depending on the context). It is to be understood that unless otherwise stated, such “improvement” is a measure of a benefit obtained based on a comparison to devices, structures, systems or methods in the prior art. Furthermore, it is to be understood that the degree of improved performance may vary between disclosed embodiments and that no equality or consistency in the amount, degree, or realization of improved performance is to be assumed as universally applicable.

In addition, embodiments of the present disclosure may include hardware, software, and electronic components or modules that, for purposes of discussion, may be illustrated and described as if the majority of the components were implemented solely in hardware. However, one of ordinary skill in the art, and based on a reading of this detailed description, would recognize that, in at least one embodiment, the electronic based aspects of the present disclosure may be implemented in software (e.g., instructions stored on non-transitory computer-readable medium) executable by one or more processing units, such as a microprocessor and/or application specific integrated circuits. As such, it should be noted that a plurality of hardware and software-based devices, as well as a plurality of different structural components may be utilized to implement the technology of the present disclosure. For example, “servers” and “computing devices” described in the specification can include one or more processing units, one or more computer-readable medium modules, one or more input/output interfaces, and various connections connecting the components.

Reference throughout this specification to substituents is meant to indicate that one or more hydrogen atoms on the atom indicated in the expression using “substituted” is replaced with a selection from an indicated group as detailed below, provided that the indicated atom's normal valence is not exceeded, and that the substitution results in a chemically stable compound, i.e. a compound that is sufficiently robust to survive isolation from a reaction mixture.

The term “halo” or “halogen” as a group or part of a group is generic for fluoro (F), chloro (Cl), bromo (Br), iodo (I).

The term “alkyl” as a group or part of a group, refers to a hydrocarbyl group of formula CₙH₂ₙ₊₁ wherein n is a number greater than or equal to 1. Alkyl groups may be linear or branched and may be substituted as indicated herein. Generally, alkyl groups of this disclosure comprise from 1 to 20 carbon atoms, preferably from 1 to 10 carbon atoms, preferably from 1 to 8 carbon atoms, preferably from 1 to 6 carbon atoms, more preferably from 1 to 4 carbon atoms. When a subscript is used herein following a carbon atom, the subscript refers to the number of carbon atoms that the named group may contain. For example, the term “C₁₋₂₀alkyl”, as a group or part of a group, refers to a hydrocarbyl group of formula —CₙH₂ₙ₊₁ wherein n is a number ranging from 1 to 20. Thus, for example, “C₁₋₈alkyl” includes all linear or branched alkyl groups with between 1 and 8 carbon atoms, and thus includes methyl, ethyl, n-propyl, i-propyl, butyl and its isomers (e.g. n-butyl, i-butyl and t-butyl); pentyl and its isomers, hexyl and its isomers, etc. A “substituted alkyl” refers to an alkyl group substituted with one or more substituent(s) (for example 1 to 3 substituent(s), for example 1, 2, or 3 substituent(s)) at any available point of attachment.

When the suffix “ene” is used in conjunction with an alkyl group, i.e. “alkylene”, this is intended to mean the alkyl group as defined herein having two single bonds as points of attachment to other groups. As used herein, the term “alkylene” also referred as “alkanediyl”, by itself or as part of another substituent, refers to alkyl groups that are divalent, i.e., with two single bonds for attachment to two other groups. Alkylene groups may be linear or branched and may be substituted as indicated herein. Non-limiting examples of alkylene groups include methylene (—CH₂—), ethylene (—CH₂—CH₂—), methylmethylene (—CH(CH₃)—), 1-methyl-ethylene (—CH(CH₃)—CH₂—), n-propylene (—CH₂—CH₂—CH₂—), 2-methylpropylene (—CH₂—CH(CH₃)—CH₂—), 3-methylpropylene (—CH₂—CH₂—CH(CH₃)—), n-butylene (—CH₂—CH₂—CH₂—CH₂—), 2-methylbutylene (—CH₂—CH(CH₃)—CH₂—CH₂—), 4-methylbutylene (—CH₂—CH₂—CH₂—CH(CH₃)—), pentylene and its chain isomers, hexylene and its chain isomers.

The term “alkenyl” as a group or part of a group, refers to an unsaturated hydrocarbyl group, which may be linear, or branched, comprising one or more carbon-carbon double bonds. Generally, alkenyl groups of this disclosure comprise from 3 to 20 carbon atoms, preferably from 3 to 10 carbon atoms, preferably from 3 to 8 carbon atoms. When a subscript is used herein following a carbon atom, the subscript refers to the number of carbon atoms that the named group may contain. Examples of C₃₋₂₀alkenyl groups are ethenyl, 2-propenyl, 2-butenyl, 3-butenyl, 2-pentenyl and its isomers, 2-hexenyl and its isomers, 2,4-pentadienyl, and the like.

The term “cycloalkyl”, as a group or part of a group, refers to a cyclic alkyl group, that is a monovalent, saturated, hydrocarbyl group having 1 or more cyclic structure, and comprising from 3 to 20 carbon atoms, more preferably from 3 to 10 carbon atoms, more preferably from 3 to 8 carbon atoms; more preferably from 3 to 6 carbon atoms. Cycloalkyl includes all saturated hydrocarbon groups containing 1 or more rings, including monocyclic, bicyclic groups or tricyclic. The further rings of multi-ring cycloalkyls may be either fused, bridged and/or joined through one or more spiro atoms. When a subscript is used herein following a carbon atom, the subscript refers to the number of carbon atoms that the named group may contain. For example, the term “C₃. 20cycloalkyl”, a cyclic alkyl group comprising from 3 to 20 carbon atoms. For example, the term “C₃₋₁₀cycloalkyl”, a cyclic alkyl group comprising from 3 to 10 carbon atoms. For example, the term “C₃₋₈cycloalkyl”, a cyclic alkyl group comprising from 3 to 8 carbon atoms. For example, the term “C₃₋₆cycloalkyl”, a cyclic alkyl group comprising from 3 to 6 carbon atoms. Examples of C₃₋₁₂cycloalkyl groups include but are not limited to adamantly, cyclopropyl, cyclobutyl, cyclopentyl, cyclohexyl, cycloheptyl, cyclooctyl, bicycle[2.2.1]heptan-2yl, (1S,4R)-norbornan-2-yl, (1R,4R)-norbornan-2-yl, (1S,4S)-norbornan-2-yl, (1R,4S)-norbornan-2-yl.

When the suffix “ene” is used in conjunction with a cycloalkyl group, i.e. cycloalkylene, this is intended to mean the cycloalkyl group as defined herein having two single bonds as points of attachment to other groups. Non-limiting examples of “cycloalkylene” include 1,2-cyclopropylene, 1,1-cyclopropylene, 1,1-cyclobutylene, 1,2-cyclobutylene, 1,3-cyclopentylene, 1,1-cyclopentylene, and 1,4-cyclohexylene.

Where an alkylene or cycloalkylene group is present, connectivity to the molecular structure of which it forms part may be through a common carbon atom or different carbon atom. To illustrate this applying the asterisk nomenclature of this disclosure, a C₃alkylene group may be for example *—CH₂CH₂CH₂—*, *—CH(—CH₂CH₃)—* or *—CH₂CH(—CH₃)—*. Likewise, a C₃cycloalkylene group may be

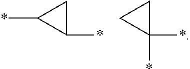

The term “aryl”, as a group or part of a group, refers to a polyunsaturated, aromatic hydrocarbyl group having a single ring (i.e. phenyl) or multiple aromatic rings fused together (e.g. naphthyl), or linked covalently, typically containing 6 to 20 atoms; preferably 6 to 10, wherein at least one ring is aromatic. The aromatic ring may optionally include one to two additional rings (either cycloalkyl, heterocyclyl or heteroaryl) fused thereto. Examples of suitable aryl include C₆₋₂₀aryl, preferably C₆₋₁₀aryl, more preferably C₆₋₈aryl. Non-limiting examples of aryl comprise phenyl, biphenylyl, biphenylenyl, or 1- or 2-naphthanelyl; 1-, 2-, 3-, 4-, 5- or 6-tetralinyl (also known as “1,2,3,4-tetrahydronaphtalene); 1-, 2-, 3-, 4-, 5-, 6-, 7- or 8-azulenyl, 4-, 5-, 6 or 7-indenyl; 4- or 5-indanyl; 5-, 6-, 7- or 8-tetrahydronaphthyl; 1,2,3,4-tetrahydronaphthyl; and 1,4-dihydronaphthyl; 1-, 2-, 3-, 4- or 5-pyrenyl. A “substituted aryl” refers to an aryl group having one or more substituent(s)(for example 1, 2 or 3 substituent(s), or 1 to 2 substituent(s)), at any available point of attachment.

The term “alkoxy” or “alkyloxy”, as a group or part of a group, refers to a group having the formula —OR^{b} wherein R^{b} is alkyl as defined herein above. Non-limiting examples of suitable alkoxy include methoxy, ethoxy, propoxy, isopropoxy, butoxy, isobutoxy, sec-butoxy, tert-butoxy, pentyloxy and hexyloxy.

The term “heteroalkyl” as a group or part of a group, refers to an acyclic alkyl wherein one or more carbon atoms are replaced by at least one heteroatom selected from the group comprising O, Si, S, B, and P, with the proviso that the chain may not contain two adjacent heteroatoms. This means that one or more —CH₃ of the acyclic alkyl can be replaced by —OH for example and/or that one or more —CR₂— of the acyclic alkyl can be replaced by O, Si, S, B, and P.

The term “cyclopentadienyl” as a group or part of a group, refers to a group having the formula (V)

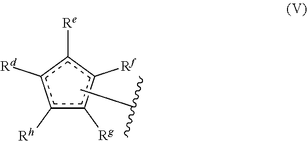

wherein R^{d}, R^{e}, R^{f}, R^{g}, R^{h} are each independently selected from the group consisting of hydrogen, alkyl, alkenyl, alkoxy, or heteroalkyl as defined herein above. As disclosed herein, cyclopentadienyl is a 5-member carbon ring bound to metal such as hafnium and/or zirconium through covalent η5-bonds. Thus, for example, “cyclopentadienyl” refers to both hydrogenated cyclopenta-2,4-dien-1-yl (Cp) and substituted cyclopenta-2,4-dien-1-yl, such as, methyl-cyclopenta-2,4-dien-1-yl (MeCp), ethyl-cyclopenta-2,4-dien-1-yl (EtCp), and n-propyl-cyclopenta-2,4-dien-1-yl (n-PrCp).

The term “aryl”, as a group or part of a group, refers to a polyunsaturated, aromatic hydrocarbyl group having a single ring (i.e. phenyl) or multiple aromatic rings fused together (e.g. naphthyl), or linked covalently, typically containing 6 to 20 atoms; preferably 6 to 10, wherein at least one ring is aromatic. The aromatic ring may optionally include one to two additional rings (either cycloalkyl, heterocyclyl or heteroaryl) fused thereto. Examples of suitable aryl include C₆₋₂₀aryl, preferably C₆₋₁₀aryl, more preferably C₆₋₈aryl. Non-limiting examples of aryl comprise phenyl, biphenylyl, biphenylenyl, or 1- or 2-naphthanelyl; 1-, 2-, 3-, 4-, 5- or 6-tetralinyl (also known as “1,2,3,4-tetrahydronaphtalene); 1-, 2-, 3-, 4-, 5-, 6-, 7- or 8-azulenyl, 4-, 5-, 6 or 7-indenyl; 4- or 5-indanyl; 5-, 6-, 7- or 8-tetrahydronaphthyl; 1,2,3,4-tetrahydronaphthyl; and 1,4-dihydronaphthyl; 1-, 2-, 3-, 4- or 5-pyrenyl. A “substituted aryl” refers to an aryl group having one or more substituent(s)(for example 1, 2 or 3 substituent(s), or 1 to 2 substituent(s)), at any available point of attachment.

In this disclosure, “gas” can include material that is a gas at normal temperature and pressure (NTP), a vaporized solid and/or a vaporized liquid, and can be constituted by a single gas or a mixture of gases, depending on the context. A gas other than the process gas, i.e., a gas introduced without passing through a gas distribution assembly, other gas distribution device, or the like, can be used for, e.g., sealing the reaction space, and can include a seal gas, such as a rare gas.

In some cases, the term “precursor” can refer to a compound that participates in the chemical reaction that produces another compound, particularly a compound that constitutes a film matrix or a main skeleton of a film; the term “reactant” can be used interchangeably with the precursor.

As used herein, the term “substrate” can refer to any underlying material or materials that can be used to form, or upon which, a device, a circuit, or a film can be formed. The “substrate” may be continuous or non-continuous; rigid or flexible; solid or porous; and combinations thereof. The substrate may be in any form, such as a powder, a plate, or a workpiece. Substrates in the form of a plate may include wafers in various shapes and sizes. A substrate can include a bulk material, such as silicon (e.g., single-crystal silicon), other Group IV materials, such as germanium, or other semiconductor materials, such as Group II-VI or Group III-V semiconductor materials, and can include one or more layers overlying or underlying the bulk material. Further, the substrate can include various features, such as recesses, protrusions, and the like formed within or on at least a portion of a layer of the substrate. By way of examples, a substrate can include bulk semiconductor material and an insulating or (high-k) dielectric material layer overlying at least a portion of the bulk semiconductor material.

As used herein, the term “film” and/or “layer” can refer to any continuous or non-continuous structure and material, such as material deposited by the methods disclosed herein. For example, a film and/or layer can include two-dimensional materials, three-dimensional materials, nanoparticles or even partial or full molecular layers or partial or full atomic layers or clusters of atoms and/or molecules, or layers consisting of isolated atoms and/or molecules. A film or layer may comprise material or a layer with pinholes, which may or may not be continuous.

In this disclosure, the following abbreviations of chemical structures are used: Cp stands for cyclopentadienyl, Me stands for methyl; Et stands for ethyl; n-Pr stands for n-propyl; i-Pr stands for i-propyl or isopropyl, n-Bu stands for n-butyl; t-Bu stands for t-butyl or tert-butyl.

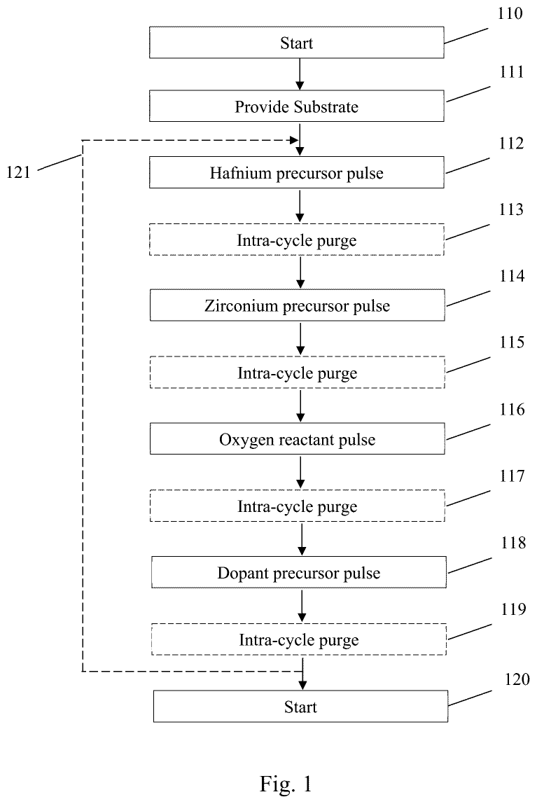

Turning now to the figures, FIG. 1 illustrates a method 100 in accordance with exemplary embodiments of the disclosure. In general, the technology disclosed herein relates to the field of capacitor devices, and more specifically to a method for forming a capacitor structure comprising a doped HZO layer showing a high dielectric constant value κ in a specific voltage range. An important step of the doped HZO layer formation referred to herein can comprise the selection of an appropriate dopant precursor which comprises three or four valence electrons and an atomic radius which is less than the atomic radius of an Hf or Zr element of the HZO layer. Advantageously, the current inventors have found that the herein disclosed method allows to alter the CV curve, resulting in a dielectric constant value κ at a desired high level and within a desired voltage range, while still experiencing low leakage. To elaborate, one of the challenges in doped HZO layers, and in particular when used in MIM CAPS, is to push ferroelectric HZO into an antiferroelectric conduction, which boost the dielectric constant κ at the desired voltage thus shifting the CV curve so that a high κ at a desired voltage can be reached. In contrast to the state of the art, the current disclosure allows to design a doped HZO layer by using appropriate dopants such that the ferroelectric properties of the HZO layer are changed to a primarily tetragonal composition, thus shifting the maximum dielectric constant κ to the region of interest, which boosts the dielectric constant κ in the region needed compared to a undoped HZO layer.

As set forth in more detail below, various embodiments of the present disclosure relate to a method for forming a doped hafnium zirconium oxide (HZO) layer on a substrate, the method comprising the steps of:
a) providing a substrate in a reaction chamber;
b) executing one or more cycles, a cycle comprising
   i. a hafnium precursor pulse, wherein at least a part of the substrate is contacted with one or more hafnium precursor by introducing said one or more hafnium precursor in the reaction chamber;
   ii. a zirconium precursor pulse, wherein at least a part of the substrate is contacted with one or more zirconium precursor by introducing said one or more zirconium precursor in the reaction chamber;
   iii. an oxygen reactant pulse, wherein at least a part of the substrate is contacted with one or more oxygen reactant by introducing said one or more oxygen reactant in the reaction chamber; and
   iv. a dopant precursor pulse, wherein at least a part of the substrate is contacted with one or more dopant precursor by introducing said one or more dopant precursor in the reaction chamber,
      thereby forming a doped HZO layer;
         wherein said dopant precursor comprises a dopant element characterized by having three or four valence electrons and an atomic radius which is less than the atomic radius of an Hf or Zr element of the HZO layer.

FIG. 1 describes an exemplary embodiment of the above method for forming a doped hafnium zirconium oxide (HZO) layer on a substrate. The method starts (110) with providing a substrate in a reaction chamber (111). The cyclical deposition process comprises contacting a hafnium precursor with at least a part of the substrate in a hafnium precursor pulse (112). Optionally, the reaction chamber is purged (113) after the hafnium precursor pulse (112). Then, a zirconium precursor is provided to the reaction chamber in a zirconium precursor pulse (114). Optionally, the reaction chamber can be purged (115) after the zirconium precursor pulse. Further, the cyclical deposition process comprises providing an oxygen reactant pulse (116) to the reaction chamber. Optionally, the reaction chamber can be purged (117) after the oxygen reactant pulse. Then, a dopant precursor is provided to the reaction chamber in a dopant precursor pulse (118). Optionally, the reaction chamber can be purged (119) after the dopant precursor pulse. The hafnium precursor pulse (112), the zirconium precursor pulse (114), the oxygen reactant pulse (116), the dopant precursor pulse (118) and the optional purges (113,115,117,119) can be repeated (121) any number of times, in any order, in certain cycles of the method illustrated in FIG. 1, one or more precursors (e.g., hafnium precursor pulse (112), the zirconium precursor pulse (114), the oxygen reactant pulse (116), the dopant precursor pulse (118) and the optional purges (113,115,117,119)) may be omitted, to obtain a doped HZO layer having a desired thickness. When a doped HZO containing layer having a desired thickness has been deposited, the method ends (120). Once the method has ended, the substrate can, for example, be subjected to additional processes to form a device structure and/or device.

In particular, the formation of a doped HZO layer on a substrate as described herein relates to a cyclical deposition process, such as an atomic layer deposition (ALD) process or a cyclical chemical vapor deposition process. ALD is a thin-film technique used to create extremely thin and precise layers of materials on substrates such that a uniform and well-controlled layer can be created on three-dimensional surfaces. Such a cyclical deposition process may comprise one or more cycles, whereby the steps may be repeated from at least 1 cycle to at most 1000 cycles, or from at least 2 cycles to at most 100 cycles, or from at least 5 cycles to at most 50 cycles. The skilled person understands that different orders of pulses within one cycle may be possible.

As used herein, the term “deposition” or “cyclic deposition” or “cyclic deposition process” or “cyclical deposition process” refers to a sequential introduction of precursors into a reaction chamber to deposit a layer or film over a substrate and includes processing techniques such as atomic layer deposition (ALD), cyclical chemical vapor deposition (cyclical CVD), and hybrid cyclical deposition processes that include an ALD component and a cyclical CVD component. The term “atomic layer deposition” (ALD) refers to a vapor deposition process in which deposition cycles, typically a plurality of consecutive deposition cycles, are conducted in a process chamber. The term atomic layer deposition, as used herein, is also meant to include processes designated by related terms, such as chemical vapor atomic layer deposition, atomic layer epitaxy (ALE), molecular beam epitaxy (MBE), gas source MBE, organometallic MBE, and chemical beam epitaxy, when performed with alternating pulses of precursor(s)/reactive gas(es), and purge (e.g., inert carrier) gas(es). Generally, for ALD processes, during each cycle, a (metal) precursor is introduced to a reaction chamber and is chemisorbed to a deposition surface (e.g., a substrate surface that can include a previously deposited material from a previous ALD cycle or other material) and forming material, e.g. about a monolayer or sub-monolayer of material, or several monolayers of material, or a plurality of monolayers of material, that does not readily react with additional precursor (i.e., a self-limiting reaction). Thereafter, in some cases, a reactant (e.g., another precursor or reaction gas) may subsequently be introduced into the process chamber for use in converting the chemisorbed precursor to the desired material on the deposition surface. The reactant can be capable of further reaction with the precursor. Purging steps can be utilized during one or more repetitions, e.g. during each deposition step, to remove any excess precursor from the process chamber and/or remove any excess reactant and/or reaction byproducts from the reaction chamber. Note that, as used herein, ALD processes are not necessarily comprised of a sequence of self-limiting surface reactions. Advantageously, the method of the present disclosure allows to form dipole layers that do not require full film closure to work. Hence, allowing faster deposition with a larger error-tolerance compared to what is disclosed in the state of the art.

In preferred embodiments, a deposition process as disclosed herein refers to an atomic layer deposition process. Typically, one deposition cycle may form a film or layer of about 0.10 nm. However, the experimental thickness may vary depending on the amount and type of cycles and available reaction sites on the substrate. In preferred embodiments, the method as disclosed herein provides that the HZO layer has an average thickness of 1 nm or less, or 0.75 nm or less, preferably 0.50 nm or less, or 0.4 nm or less, or 0.3 nm or less, preferably 0.25 nm or less, or 0.2 nm or less, more preferably 0.10 nm or less. In some embodiments, the HZO layer is grown at a rate of 0.10 nm or less per alternating pulses of precursor(s)/reactive gas(es), and purge (e.g., inert carrier) gas(es).

In order to create a doped HZO layer on a substrate, a first pulse with a hafnium precursor, a second pulse with a zirconium precursor, and a third pulse with an oxygen reactant are introduced inside the reaction chamber such that at least part of the substrate is in contact with the hafnium precursor, zirconium precursor, oxygen reactant and/or dopant precursor to form a desired thin film. A precursor pulse typically lasts from at least 0.01 is to at most 120s, while an oxygen reactant pulse lasts from at least 0.1s to at most 20s. One precursor will typically react with the substrate's surface, while the other precursors remain inert during that reaction. During the repeated deposition cycles, the precursors are introduced one at a time, allowing them to react with the surface in a self-limiting manner. When the first precursor is introduced, it reacts with the substrate's surface, forming a chemisorbed layer. Typically, excess precursor is purged or removed from the reaction chamber before the next precursor is introduced, which will then react with the already formed chemisorbed layer from the previous step, thus forming a new layer. Once all available reactive sites on the substrate's surface are saturated, the reaction will stop and a thin film which has grown atom-by-atom is created, ensuring precise control over the film thickness.

In order to develop a material having a linear CV characteristic and a dielectric constant value κ above 40 in a specific voltage range, a dopant precursor pulse is added to the reaction chamber such that at least a part of the substrate is contacted with one or more dopant precursor, thereby forming a doped HZO layer. Such a doped HZO layer is thus a layer of material formed of hafnium oxide (HfO₂) on a substrate that has intentionally been modified or doped with certain elements or impurities. Doping involves introducing small amounts of specific atoms or ions into the host material's crystal lattice. This modification can alter the material's electrical, optical or other properties to suit desired functionalities. When using dopants to improve the electrical performances, typically the dielectric constant value κ is enhanced, as well as reducing current leakage and improving its interference with other materials in e.g. semiconductor devices.

When using a dopant precursor comprising a dopant element having three or four valence electrons and an atomic radius which is less than the atomic radius of an Hf or Zr element of the HZO layer, it is possible to push the HZO material into an appropriate Morphotropic Phase Boundary (MPB). Thus, doping the HZO layer with small ionic radius elements stabilizes the tetragonal phase of the HZO layer such that a Morphotropic Phase Boundary (MPB) is reached between the orthorhombic and tetragonal phases of the HZO layer to allow a change in the polarization switching voltage of the HZO layer. At a certain percentage of added dopant, the material adopts a primarily tetragonal phase composition, which results in a boost in the dielectric constant value κ of the HZO layer to peak at the voltage region of interest. Additionally, changing the polarization switching voltage of the HZO layer changes the Capacitance Voltage (CV) linearity of the HZO layer, thus tuning the shape of the capacitance-voltage (CV) curve, and arriving at a better linearity. Ideally, the dielectric constant value (κ) of said doped HZO layer is above 35 at about −2 and −3 MV/cm.

The MPB is a compositional region within a phase diagram of materials, where a drastic change in the crystal structure and properties can occur as the composition of the material is varied. Different crystal structures can exhibit distinct electrical, mechanical, and thermal properties. The MPB represents a composition range where two different crystal phases coexist, and relatively small changes in composition lead to significant changes in changes in the properties of the material. Ferroelectric, antiferroelectric, and paraelectric phases are different phases of the MPB and each have a different ordering of crystals in these materials. These phases relate to how electric dipoles within the material are aligned or ordered, which in turn affects their electrical, mechanical, and thermal properties. In a ferroelectric material, electric dipoles, being molecular or atomic arrangements with positive and negative charges separated, can spontaneously align in a particular direction even in the absence of an external electric field. This alignment gives rise to a permanent electric polarization that can be reversed when an external electric field is applied in the opposite direction.

In an antiferroelectric material, neighboring dipoles have opposite directions of alignment, meaning that the net polarization of the material is zero. When an external electric field is applied, the dipoles tend to align in the direction opposite to that of the field. Antiferroelectric materials are characterized by their abrupt changes in polarization.

In a paraelectric material, there is no spontaneous polarization at all. However, when an external electric field is applied, the material can become polarized temporarily. The polarization disappears when the field is removed. Paraelectric materials exhibit a linear relationship between polarization and electric field and are therefore often used as dielectric materials in capacitors.

These different phases can exist in certain materials due to the arrangement of their atoms or molecules and the interaction between them. The phase transitions between these different states can have profound effects on the material's properties, and understanding and controlling these transitions are crucial when designing capacitors and utilizing these materials for various applications.

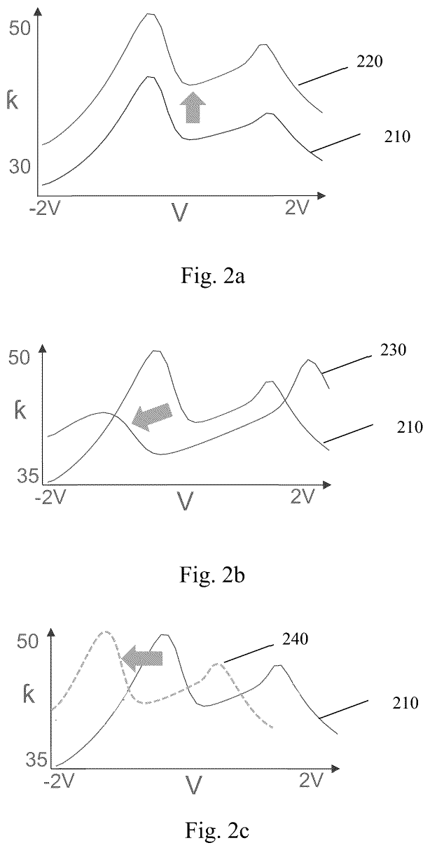

Therefore, when doping the HZO layer with selected elements at precise concentrations, the antiferroelectric/paraelectric phase boundary can be triggered and the appropriate crystal structure can be achieved. The inventors surprisingly found that when a dopant element having three or four valence electrons and an atomic radius which is less than the atomic radius of an Hf or Zr element of the HZO layer is used to create a doped HZO layer, a primary tetragonal phase composition is triggered in the formed material. The dominant or primary crystal structure of the material is then tetragonal, whereby the crystals have three axes of different length, two of which are equal and perpendicular to each other, and the third is longer or shorter, while the angles between the axes are all right angles. By doping the HZO layer using such a dopant precursor, a primary tetragonal phase composition of the HZO layer will occur which allow for a shift of the maximum dielectric constant value κ such that a peak of the value κ at the region of interest is accomplished, will having a nearly flat CV characteristics. FIGS. 2a-2c illustrate the different modifications possible to a CV curve by doping the HZO layer. In FIG. 2a, a first type of dopant is used to bring the CV curve of an undoped HZO layer (210) up. By doing so, the shape of the CV curve of the doped HZO layer (220) remains essentially the same, however an increase in the value κ at approximately the same voltage is achieved. The inventors have found that e.g. using Al as dopant can create this effect. Doping the HZO layer with an Al dopant precursor has the effect that the non-polar phases are reduced due to oxygen vacancy formation and a MPB with approximately a 50%-50% orthorhombic and tetragonal phase composition is achieved. The dopant precursor preferably being a low-reactivity Aluminium precursor represented by the general formula Al(R¹)₃, wherein each R¹ is independently selected from the group consisting of hydrogen, halogen, alkyl, alkenyl, N(R²)₂, cycloalkyl, and alkoxy; and wherein each R² is chosen from hydrogen, alkyl, or alkenyl. Alternatively, using Ge as dopant for a Zr-rich HZO layer has a similar effect.

In FIG. 2b, a second type of dopant is used to stretch the CV curve of an undoped HZO layer (210). By doing so, the shape of the CV curve of the doped HZO layer (230) changes so that the peaks shift to higher fields while reducing the maximum value of x. The inventors have found that e.g. using Si as dopant can create this effect. Doping the HZO layer with a Si dopant precursor has the effect that the tetragonal phase and the barrier between the polar states is increased. The increase in the tetragonal phase is due to strain and a smaller electronegativity effect which makes it more difficult to polarize the lattice. This has the result that a moderate high κ value is reached at a different voltage than with an undoped HZO layer. The dopant precursor preferably being a low-reactivity Silicon precursor selected from the list consisting of silicon tetraacetate (Si(OOCCH₃)₄), and Si(R³)₄, wherein each R³ is independently selected from the group consisting of hydrogen, halogen, alkyl, alkenyl, N(R⁴)₂, cycloalkyl, and alkoxy; and wherein each R⁴ is chosen from hydrogen, alkyl, or alkenyl. Alternatively, using Ge as dopant for a Zr-rich HZO layer has a similar effect.

In some examples, using a dopant e.g., Al, Si and/or Ge in the HZO layer may have a combination of the aforementioned effects on the CV curve.

Silicon doping of HZO can be extremely beneficial when between 2.0 to 4.5% of doping is used. The percentage of silicon doping is calculated as follows:

Doping %=Si/(Si+Hf+Zr)*100

To target these concentrations, a low-reactivity Si precursor including but not limited to tris(dimethylalmino)silane (TDMAS) can be used. However, such a precursor may also be known to have poor nucleation, meaning that while doping, it may be possible that the full/uniform coverage of the wafer is not achieved, leading to both inter-wafer and wafer-to-wafer variation. It is proposed to implement a multiple rapid pulsing scheme with TDMAS pulsing, to improve the reproducibility of Si-doping of HZO. By utilizing repeating micropulses of the TDMAS precursor during dopant pulse steps, it is possible to get a good distribution of the surface silicon, despite a poor nucleation. Since the absorption of the Si precursor may be self-limiting as long as operating temperatures are kept below the decomposition temperature of TDMAS, no excessive silicon doping may occur with these multiple rapid pulses, while better nucleation and surface coverage is achieved. That way, an increased wafer-to-wafer reproducibility in addition to inter-wafer silicon doping uniformity in Si-doped HZO is reached.

Additionally, silicon precursors based on water as a co-reactant and water based processes can easily be incorporated into water based HfO₂ ALD processes. Although water has many advantages, co-reactants such as O₃, O₂ and H₂O₂ can also be used. Examples of such water based silicon precursors are silicon tetraacetate (Si(OOCCH₃)₄), and Si(R³)⁴ as defined herein. These precursors leverage the high reactivity with water and in combination with an ALD process for SiO₂ would ensure successful incorporation into HfO₂ based ALD processes. Various sub cycles of Si or Hf will tune the ratio of these elements in the final films. The deposition temperature can be from 150-450° C. with a more optimized range around 300° C. Additionally, a post deposition anneal may be required to achieve certain film properties such as right phase for either dielectric- or ferro-based films.

In FIG. 2c, a third type of dopant is used to shift the CV curve of an undoped HZO layer (210). By doing so, the shape of the CV curve of the doped HZO layer (240) remains approximately the same, while the peaks shift to higher fields while still maintaining the maximum value of κ. The inventors have found that introducing a low iconic radius dopant such as Ge can create this effect. Doping the HZO layer with an Ge dopant precursor has the effect that the material is forced to adopt a primarily tetragonal phase composition due to the creation of strain and an increase in polar lattice due to a higher electronegativity. This will result in a shift of the maximum peak of the κ value to a different region, as well as promoting better linearity. The dopant precursor preferably being a low-reactivity Germanium precursor represented by the general formula Ge(R⁵)₄, wherein each R^{S} is independently selected from the group consisting of hydrogen, halogen, alkyl, alkenyl, N(R⁶)₂, cycloalkyl, and alkoxy; and wherein each R⁶ is chosen from hydrogen, alkyl, or alkenyl. However, it should be noted that the present disclosure is not limited to Silicon or Germanium dopants and also other group II-VI elements (e.g. Carbon, Phosphorus, Arsenic, Boron, Indium, Nickel, or Antimony) may be used.

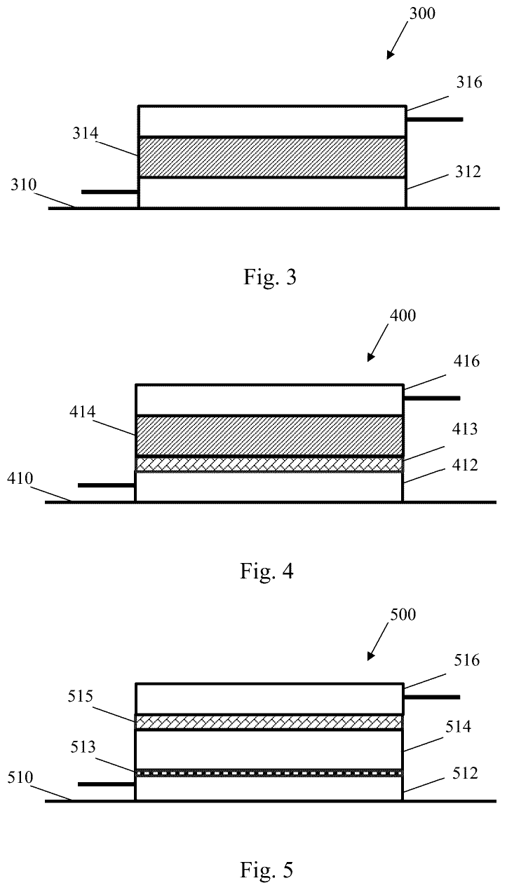

The inventors surprisingly found that HZO layers having a higher percentage of Zr, preferably within a range of 60% to 80% of Zr, and doped with a lower percentage of Ge, less than about 3%, or less than about 2%, or less than about 1.5% of Ge, or between about 0.25% to 1.5% of Ge, can be advantageous for boosting higher a phases in a voltage region of interest, while being less sensitive to the thickness and composition of the HZO layers. In an example, a Metal Oxide and Ozone based HZO process(MO-O3)(e.g., as described with respect to FIG. 1) with germanium-doping may be used to produce a material stack comprising an HZO layer having a thickness sufficient to form crystalline structures rather than to maintain an amorphous structure. In some examples, the thickness of the HZO layer was found to be greater than or equal to 45 angstroms (45 Å), however, other thicknesses are possible and claimed subject matter is not limited in this regard. The material stack (e.g., see exemplary MIM CAP 300 illustrated in FIG. 3) can comprise a top electrode made of titanium nitride (TiN) deposited via Atomic Layer Deposition (ALD). In some examples, a thermal budget of greater than about 400° C., may achieve a capacitance-to-area density (C/A) greater than 70 fF/um2 and in some instances greater than 100 fF/um2. Such C/A may be achieved applying a negative bias in the range of about −1.5 V to about −1.0 V or applying a positive bias in the range of about 1.5 V to about 1.0 V, about here means+/−0.25 V. Using the above described methods a C/A much greater than 100 fF/um2 may be achieved and claimed subject matter is not limited in this regard.

When doping a HZO layer with a specific dopant, the κ value will be altered which will influence the electric permittivity of the material. The higher the κ value, the better the ability of the capacitor to store electric energy in an electrical field. To maximize the charge that a capacitor can hold, the insulator material, being the doped HZO layer, needs to have an as high permittivity as possible, while also having an as high as possible breakdown voltage and an as low as possible loss of frequency. So, depending on the final requirements of the doped HZO layer, a variation in the thickness of the HZO layer, the selected doping elements such as Al, Si, or Ge, a variation in the percentage of doping element used, and environment settings when creating the doped HZO layer can provide for a variation in the reached maximum κ value and in the CV characteristics such as a stretched or shifted CV curve.

Typically, a cycle comprises three or more pulses. In some embodiments, at least one pulse involves a self-limiting surface reaction. In some embodiments, all pulses involve a self-limiting surface reaction. In some embodiments, an oxygen reactant pulse is carried out after each hafnium precursor pulse and/or after each zirconium precursor pulse. Using an oxygen reactant pulse after a precursor pulse allows to create thin films on the provided substrate. After the precursor pulse is introduced, it is important to ensure that any excess or unreacted precursor is removed from the reaction chamber before introducing the next reactant. By doing so, unwanted accumulation of precursor molecules is prevented which could otherwise lead to undesired film properties or non-uniformity of the film. Since the precursor pulse also involves chemisorption, where precursor molecules will absorb onto the substrate's surface and react with it, providing an oxygen reactant pulse will help to complete the surface reactions and promote the formation of the desired film on the substrate, assists in removing any residual absorbed precursor molecules and reduce the existence of impurities and defects in the formed film.

In some embodiments, the dopant precursor pulse is carried out after the hafnium precursor pulse, without any intervening oxygen reactant pulse. In the hafnium precursor pulse, the hafnium precursor is provided into the reaction chamber. In the dopant precursor pulse, the dopant compound is provided into the reaction chamber. Hence, a thin film is formed on at least a part of the substrate containing Hafnium and dopant. In some embodiments, the dopant precursor pulse is carried out after the zirconium precursor pulse, without any intervening oxygen reactant pulse. In the zirconium precursor pulse, the zirconium precursor is provided into the reaction chamber. In the dopant precursor pulse, the dopant compound is provided into the reaction chamber. Hence, a thin film is formed on at least a part of the substrate containing at least zirconium and dopant.

It shall be understood that any two steps and/or pulses can be separated by a purge. Thus, in some embodiments, the step of contacting the one or more precursor and/or the step of contacting the dopant compound are separated by a purge. In some embodiments, subsequent cycles are separated by a purge.

In particular embodiments, the method as disclosed herein provides that the one or more cycle, comprising the steps of contacting one or more precursor with at least a part of the substrate and providing the nitrogen compound or another noble gas into the reaction chamber, is quasi free from oxygen, and preferably fully oxygen free. More specifically, the disclosed method provides that the deposition of the HZO film is free from oxygen contaminants, thus lowering the equivalent oxide thickness (EOT) of the dipole and the amount of deposition defects.

In some embodiments, the hafnium precursor pulse, the zirconium precursor pulse, the oxygen reactant pulse and/or the dopant precursor pulse comprises a plurality of micropulses. Micropulsing is a technique used to maintain fine control over thin-film growth, composition and the envisaged properties. Micropulsing involves delivering very short bursts of precursor or reactant gases with precise timing and allows for a better utilization of the precursor material. By delivering small, controlled amounts of precursor, it can be ensured that most of the precursor molecules are chemically absorbed and are able to react with the substrate. It is particularly valuable in processes that require precise atomic or molecular layer deposition and where avoiding excessive precursor exposure is critical for achieving desired film characteristics, as is the case for MIM CAPS having a peak of κ at a voltage region of interest.

Non-limiting examples of dopant elements may include Aluminium, Silicon, Nickel, Germanium, Gallium and Carbon.

In particular embodiments, the method as disclosed herein provides for a variation in concentration of the dopant element in the HZO layer. The concentration of the dopant element ranges between 0.50 and 8.0% of the relative dopant element concentration, more particularly between 1.0 and 5.0% of the relative dopant element concentration, and even more particularly between 2.0 and 4.50% of the relative dopant element concentration.

Alternatively, the molar atomic concentration of the dopant element ranges between 0.50 at. % and 15.0 at. %, more in particular between 0.50 at. % and 10.0 at. %, more in particular between 1.0 at. % and 5.0 at. %, and more in particular between 2.00 at. % and 4.50 at. %. Preferably, the dopant element comprises a molar atomic percentage of less than 10.0 at. %, such as less than 9.0 at. %, or less than 8.0 at. %, or less than 7.0 at. %, or less than 6.0 at. %, or less than 5.0 at. %, or less than 4.0 at. %, or less than 3.0 at. %, or less than 2.0 at. %, or less than 1.0 at. %, or less than 0.5 at. %.

In particular embodiments, the dopant element is Al. Further, the dopant precursor is a low-reactivity precursor, preferably a low-reactivity Aluminium precursor represented by the general formula Al(R¹)₃, wherein each R¹ is independently selected from the group consisting of hydrogen, halogen, alkyl, alkenyl, N(R²)₂, cycloalkyl, and alkoxy; and wherein each R² is chosen from hydrogen, alkyl, or alkenyl.

In preferred embodiments, each R¹ is independently selected from the group consisting of hydrogen, halogen, C₁₋₈alkyl, C₂₋₈alkenyl, C₃₋₈cycloalkyl, and C₁₋₈alkoxy; and each R² is chosen from hydrogen, C₁₋₈alkyl, or C₂₋₈alkenyl.

In more preferred embodiments, each R¹ is independently selected from the group consisting of hydrogen, halogen, C₁₋₈alkyl, C₂₋₈alkenyl, C₃₋₈cycloalkyl, and C₁₋₈alkoxy; and each R² is chosen from hydrogen, C₁₋₄alkyl, or C₂₋₄alkenyl.

In particular embodiments, said Aluminium precursor is selected from the list consisting of aluminum hydride (AlH₃), aluminum trifluoride (AlF₃), aluminum trichloride (AlCl₃), aluminum tribromide (AlBr₃), aluminum triiodide (AlI₃), trimethylaluminum (Al(CH₃)₃), triethylaluminum (Al(C₂H₅)₃, tri(isopropyl)aluminum (Al(ⁱPr)₃), tetra-n-butylaluminum (Al(C₄H₉)₃), tetra-t-butylaluminum (Al(O^{t}Bu)₃), aluminum methoxide (Al(OCH₃)₃), aluminum ethoxide (Al(OC₂H₅)₃), aluminum isopropoxide (Al(OⁱPr)₃), aluminum n-butoxide (Al(OC₄H₉)₃), and aluminum t-butoxide (Al(OBu)₃).

In particular embodiments, the dopant element is Si. Further, the dopant precursor is a low-reactivity precursor, said dopant precursor preferably being a low-reactivity Silicon precursor selected from the list consisting of silicon tetraacetate (Si(OOCCH₃)₄), and Si(R³)₄, wherein each R³ is independently selected from the group consisting of hydrogen, halogen, alkyl, alkenyl, N(R⁴)₂, cycloalkyl, and alkoxy; and wherein each R⁴ is chosen from hydrogen, alkyl, or alkenyl. In preferred embodiments, each R³ is independently selected from the group consisting of hydrogen, halogen, C₁₋₈alkyl, C₂₋₈alkenyl, C₃₋₈cycloalkyl, and C₁₋₈alkoxy; and each R⁴ is chosen from hydrogen, C₁₋₈alkyl, or C₂₋₈alkenyl.

In more preferred embodiments, each R³ is independently selected from the group consisting of hydrogen, halogen, C₁₋₄alkyl, C₂₋₄alkenyl, C₃₋₈cycloalkyl, and C₁₋₄alkoxy; and each R⁴ is chosen from hydrogen, C₁₋₄alkyl, or C₂₋₄alkenyl.

In particular embodiments, said silicon precursor is selected from the list consisting of silane (SiH₄), silicon tetrafluoride (SiF₄), silicon tetrachloride (SiCl₄), silicon tetrabromide (SiBr₄), silicon tetraiodide (SiI₄), tetramethylsilane (Si(CH₃)₄), tetraethylsilane (Si(C₂H₅)₄, tetra(isopropyl)silane (Si(ⁱPr)₄), tetra-n-butylsilane (Si(C₄H₉)₄), tetra-t-butylysilane (Si(O^{t}Bu)₄), tetramethoxysilane (Si(OCH₃)₄), tetraethoxysilane (Si(OC₂H₅)₄), tetra(isopropoxy)silane (Si(OⁱPr)₄), tetra-n-butoxysilane (Si(OC₄H₉)₄), tetra-t-butoxysilane (Si(O^{t}Bu)₄), and tris(dimethylamino)silane (Si(N[CH₃]₂)₃).

In particular embodiments, the dopant element is Ge. Further, the dopant precursor is a low-reactivity precursor, preferably a low-reactivity Germanium precursor represented by the general formula Ge(R⁵)₄, wherein each R⁵ is independently selected from the group consisting of hydrogen, halogen, alkyl, alkenyl, N(R⁶)₂, cycloalkyl, and alkoxy; and wherein each R⁶ is chosen from hydrogen, alkyl, or alkenyl.

In preferred embodiments, each R⁵ is independently selected from the group consisting of hydrogen, halogen, C₁₋₈alkyl, C₂₋₈alkenyl, C₃₋₈cycloalkyl, and C₁₋₈alkoxy; and each R⁶ is chosen from hydrogen, C₁₋₈alkyl, or C₂₋₈alkenyl.

In more preferred embodiments, each R⁵ is independently selected from the group consisting of hydrogen, halogen, C₁₋₄alkyl, C₂₋₄alkenyl, C₃₋₈cycloalkyl, and C₁₋₄alkoxy; and each R⁶ is chosen from hydrogen, C₁₋₄alkyl, or C₂₋₄alkenyl.

In particular embodiments, said Germanium precursor is selected from the list consisting of germane (GeH₄), germanium tetrafluoride (GeF₄), germanium tetrachloride (GeCl₄), germanium tetrabromide (GeBr₄), germanium tetraiodide (GeI₄), tetramethylgermaniumetr (Ge(CH₃)₄), tetraethylgermanium (Ge(C₂H₅)₄, tetra(isopropyl)germanium (Ge(ⁱPr)₄), tetra-n-butylgermanium (Ge(C₄H₉)₄), tetra-t-butylgermanium (Ge(O^{t}Bu)₄), tetramethoxygermanium (Ge(OCH₃)₄), tetraethoxygermanium (Ge(OC₂H₅)₄), tetra(isopropoxy)germanium (Ge(OC₃H₇)₄), tetra-n-butoxygermanium (Ge(OC₄H₉)₄), tetra-t-butoxygermanium (Ge(OtBu)₄), and tetrakis(dimethylamino)germanium (Ge(N[CH₃]₂)₄). The inventors surprisingly found that HZO layers doped with Ge, Si and/or Al can be particularly advantageous for to force the layer to adopt a primarily tetragonal phase composition thus shifting the maximum c peaks to a region voltage region of interest, while promoting a better linearity.

A low-reactivity precursor is a chemical compound that has limited reactivity under specific conditions. In thin-film deposition techniques, such as ALD, a low-reactivity precursor is a precursor compound that does not readily undergo chemical reactions or decomposition at low temperatures or under the conditions of the deposition process.

In the described methods, the goal is to deposit thin films in a controlled and uniform manner. Using a low-reactivity precursor may be desirable because such a precursor may allow for precise control of the film growth without premature reactions or decomposition on the substrate surface.

Additionally, low-reactivity precursors are especially useful when the deposition process needs to occur at a temperature which is compatible with the substrate and the desired film properties. Since the reactivity of low-reactivity precursors can be adjusted by varying the process conditions such as temperature, pressure and exposure time, small variations may alter the reactivity of the low-reactivity precursor and thus accommodate for a specific deposition process, material and desired film characteristics.

In particular embodiments, the method as disclosed herein provides that the hafnium precursor is represented by the following general formula (I),

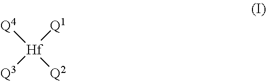

wherein Q¹, Q², Q³, Q⁴ are each independently chosen from the group consisting of halogen, alkyl, alkenyl, N(R⁷)₂, alkoxy, heteroalkyl, cycloalkyl, aryl, and cyclopentadienyl; and wherein each R⁷ is independently hydrogen, alkyl, or alkenyl.

In some embodiments, the present disclosure provides that Q¹, Q², Q³, Q⁴ are each independently chosen from the group consisting of halogen, C₁₋₈alkyl, C₂₋₈alkenyl, N(R¹)₂, C₁₋₈alkoxy, heteroC₁₋₈alkyl, C₃₋₈cycloalkyl, C₆₋₁₀aryl, and cyclopentadienyl; wherein each R⁷ is independently hydrogen, C₁₋₈alkyl, or C₂₋₈alkenyl.

In some embodiments, the present disclosure provides that Q¹, Q², Q³, Q⁴ are each independently chosen from the group consisting of halogen, C₁₋₄alkyl, C₂₋₄alkenyl, N(R⁷)₂, C₁₋₄alkoxy, heteroC₁₋₄alkyl, C₃₋₈cycloalkyl, C₆₋₁₀aryl, and cyclopentadienyl; wherein each R⁷ is independently hydrogen, C₁₋₄alkyl, or C₂₋₄alkenyl.

In particular embodiments, the method as disclosed herein provides that the hafnium precursor is chosen from the group consisting of HfCl₄, HfBr₄, HfI₄, HfMe₄, HfEt₄, Hf(nPr)₄, Hf(iPr)₄, Hf(nBu)₄, Hf(tBu)₄, Hf(NMe₂)₄, Hf(NEt₂)₄, Hf[MeEtN]₄, HfCp[(NMe₂)₃], Hf(OMe)₄, Hf(OEt)₄, Hf(OnPr)₄, Hf(OiPr)₄, Hf(OnBu)₄, Hf(OtBu)₄, Hf[(CpMe)₂][OMe][Me], Hf[(CpMe)₂][(Me)₂], Tetrakis(1-methoxy-2-methyl-2-propoxy)hafnium (Hf(mmp)₄).

Using a hafnium precursor when depositing thin films on a substrate commonly results in hafnium based materials having a high dielectric constant κ compared to traditional silicon dioxide (SiO₂), enabling better control of gate leakage and improved device performance.

In particular embodiments, the method as disclosed herein provides that the zirconium precursor is represented by the following general formula (II),

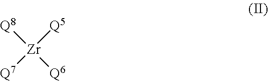

wherein Q⁵, Q⁶, Q⁷, Q⁸ are each independently chosen from the group consisting of halogen, alkyl, alkenyl, N(R⁸)₂, alkoxy, heteroalkyl, cycloalkyl, aryl, and cyclopentadienyl; wherein each R⁸ is independently hydrogen, alkyl, or alkenyl.

In some embodiments, the present disclosure provides that Q⁵, Q⁶, Q⁷, Q⁸ are each independently chosen from the group consisting of halogen, C₁₋₈alkyl, C₂₋₈alkenyl, N(R⁸), C₁₋₈alkoxy, heteroC₁₋₈alkyl, C₃₋₈cycloalkyl, C₆₋₁₀aryl, and cyclopentadienyl; wherein each R⁸ is independently hydrogen, C₁₋₈alkyl, or C₂₋₈alkenyl.

In some embodiments, the present disclosure provides that Q⁵, Q⁶, Q⁷, Q⁹ are each independently chosen from the group consisting of halogen, C₁₋₄alkyl, C₂₋₄alkenyl, N(R⁸), C₁₋₄alkoxy, heteroC₁₋₄alkyl, C₃₋₈cycloalkyl, C₆₋₁₀aryl, and cyclopentadienyl; wherein each R⁸ is independently hydrogen, C₁₋₄alkyl, or C₂₋₄alkenyl.

In particular embodiments, the method as disclosed herein provides that the zirconium precursor is chosen from the group consisting of ZrCl₄, ZrBr₄, ZrI₄, ZrMe₄, ZrEt₄, Zr(nPr)₄, Zr(iPr)₄, Zr(nBu)₄, Zr(tBu)₄, Zr(NMe₂)₄, Zr(NEt₂)₄, Zr[MeEtN]₄, ZrCp[(NMe₂)₃], Zr(OMe)₄, Zr(OEt)₄, Zr(OnPr)₄, Zr(OiPr)₄, Zr(OnBu)₄, Zr(OtBu)₄, Zr[(CpMe)₂][OMe][Me], Zr[(CpMe)₂][(Me)₂], Tetrakis(1-methoxy-2-methyl-2-propoxy)zirconium (Zr(mmp)₄).

Using a zirconium precursor when depositing thin films on a substrate commonly results in zirconium based materials having a high dielectric constant κ compared to traditional silicon dioxide (SiO₂), which helps to maintain gate capacitance while reducing gate oxide thickness in scaled-down applications. Further, using a zirconium precursor creates a barrier coating in microelectronics to prevent diffusion of metals into the dielectric layer, thus enhancing the reliability and performance of interconnect structures.

In particular embodiments, the method as disclosed herein provides that the decomposition temperature of the dopant precursor is higher compared to the operating temperature to form the doped hafnium zirconium oxide (HZO) layer. The decomposition temperature refers to the temperature at which the precursor molecule breaks down or undergoes chemical reactions that lead to the deposition of the dopant material on the substrate surface. The decomposition temperature of a dopant precursor is a critical parameter when using it in thin-film deposition processes like ALD. If the precursor decomposes at a temperature significantly lower than the process temperature, premature decomposition might occur in the gas phase, leading to the deposition of unintended reaction by-products and poor film quality. Further, precursor decomposition at the proper temperature ensures that the dopant material is deposited in its desired form without incorporating impurities or producing defective films. However, if the precursor decomposes at too high a temperature, it might not fully decompose on the substrate surface, leading to incomplete film growth and wasted precursor.

Therefore, in particular embodiments, the method as disclosed herein provides that the operating temperature to form the doped HZO layer is between 150° C. and 450° C., preferably between 250° C. and 350° C., more preferably around 300° C.

In particular embodiments, the method as disclosed herein further provides that the substrate comprises a Metal Oxide (MO) surface layer, and/or wherein said method further comprises the step of forming a Metal Oxide (MO) top layer on the doped HZO layer, thereby forming a layered doped HZO structure. Further, the MO surface layer and/or the MO top layer is in direct contact with the doped HZO layer. The metal oxide is preferably TiO₂.

FIG. 3 illustrates an exemplary MIM capacitor (300) of the disclosure, consisting of two metal layers or electrodes (312,316), separated by an insulator layer or dielectric (314) and a substrate (310) holding the two metal layers (312,316) and insulator layer (314). The insulator layer (314) is a doped HZO layer formed by the method as described in relation to FIG. 1.

Depending on the requirements of the specific MIM CAPS (300), a different dopant can be used to create the insulator or doped HZO layer (314), thus resulting in a MIM CAPS having specifically designed specifications.

In particular embodiments, the method as disclosed herein further comprising the step of providing a seed layer prior to forming the doped HZO layer, the seed layer preferably being a ZrO₂ seed layer. The seed layer serves as a foundation or nucleation site for the subsequent deposition of the doped HZO layer. Such a seed layer creates a more favorable surface for the nucleation and growth of the doped HZO layer and provides sites for the HZO precursor molecules to attach and react. This will lead to a more uniform and controlled film growth. Additionally, a seed layer may enhance the adhesion between the doped HO layer and the substrate, thus reducing the risk of delamination or peeling. In cases where the substrate's topography or surface is such that a conformal HZO deposition is challenging, the seed layer will create a smoother and more uniform surface, enabling better conformal coverage of the subsequently deposited HZO layer. In some cases, the material of the substrate may react with the HZO precursors, leading to undesirable reactions or phase changes. The seed layer will act in these cases as a buffer, preventing direct contact between the substrate and the doped HZO precursor. It shall be understood that when a seed layer is deposited on the substrate, intermixing of those layer's constituent components may occur to some extent.

For example, when a ZrO₂ containing seed layer is deposited on a substrate, at least one of the zirconium or oxygen may be incorporated into the substrate layer, for example by means of diffusion, surface segregation, or another process. In some embodiments, such intermixing can result in the formation of an interlayer containing both components of each layer.

In particular situations, for instance when a high dielectric constant value κ of above 35 between about −2 and −3 MV/cm is needed, such a deposition of a seed layer prior to the doped HZO deposition can be beneficial to reach these requirements and to reduce the above identified issues which may occur when not using such a seed layer. FIG. 4 illustrates an exemplary MIM capacitor (400) having such a seed layer (413) and a doped HZO layer (414) instead of only the doped HZO layer (314) as illustrated in FIG. 3. In an exemplary embodiment, ZrO₂ is used as a seed layer prior to the doped HZO deposition. The seed layer aids in promoting tetragonal phase and induces strain in the HZO films, thus boosting the value κ. This in combination with a precise selection of dopants can help achieve high κ values at a specific voltage range such as e.g. between −2 and −3 MV/cm. Such a combination can result in an increase of 6 to 10% of the κ value.

When an even higher a value is needed in a specific voltage range, it is possible to provide a high κ dielectric layer in series with a high κ ferroelectric layer and the combination of these layers may result in a maximum dielectric constant in the desired voltage range. Suitable high κ0 materials are for example SrTiO₃, TiO₂ or Nb₂O. There may be issues with these individual high κ layers, for example, SrTO₃ loses its high dielectric constant when scaled below 9 nm and TiO₂ is very leaky as deposited and after anneal, while Nb₂O has proven not to be very leaky as deposited however it can become leaky after anneal. However, integrating them together with a robust system such as a HZO layer doped with Si, the dielectric constant of the whole system can be boosted while the leakage is kept at an acceptable level.

Although this may be a preferred solution in some cases, the scalability when creating complex stacks may become compromised, because each layer will add to the total thickness of the stack. In situations where the maximum total thickness of the stack is a requirement, it is proposed to convert the thin layer of the bottom metal to a suitable high κ value material such as the conversion of TiN to TiO₂ or TiON by exposing the top layer of the TiN layer to O₃. Instead of depositing X nm of TiO₂, a thin layer of the bottom TiN is converted to the intended TiO₂ layer. This thus results in an extremely thin and uniform layer of bottom TiO₂.

FIG. 5 illustrates such an exemplary MIM capacitor (500) having the top of the bottom TiN layer (512) which is deposited on the substrate (510), converted to a thin layer of TiO₂ (513) by exposing it to O₃. Further, a HZO layer doped with Si (514) is then deposited by ALD using metal-organic precursors, followed by subsequently depositing a Nb₂O₅ layer (515) by ALD. Finally, a top TiN layer (516) is deposited by ALD resulting in a MIM CAPS (500) having a reduced thickness compared to an otherwise stacked layer configuration.

Typically, the doped HZO layers are formed on a substrate which is first introduced into the reaction chamber prior to the formation of the doped HZO layer. Non-limiting examples of a substrate may include a sheet or a flexible material. Substrates may also comprise carriers or sheets upon which substrates are mounted.

In particular embodiments, the method as disclosed herein provides that the doped HZO layer or the layered doped HZO structure is formed without any intervening vacuum break. Intervening vacuum breaks can introduce process pauses, which are not desirable in high-throughput manufacturing scenarios, thus leading to a more continuous and streamlined process. Also, deposition techniques, such as ALD thrive on continuous and controlled precursor exposure. Interrupting the process with vacuum breaks may introduce variations in film growth and quality, and may also increase the contamination risk since intervening vacuum breaks can potentially introduce contaminants or oxygen, particularly if the vacuum chamber is not thoroughly purged during the break. Therefore, continuous deposition without introducing intervening vacuum breaks reduces the risk of introducing impurities in the doped HZO layer.

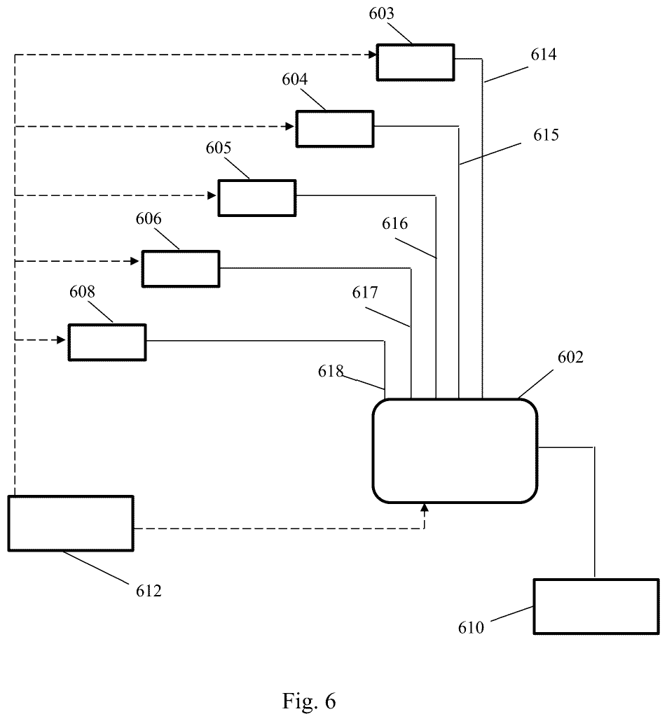

In some preferred embodiments, the present disclosure relates to a system, wherein the system is configured to perform the method as disclosed herein. FIG. 6 illustrates such a system (600) in accordance with exemplary embodiments of the disclosure. In the illustrated example, the system (600) can be used to perform a method as described herein and/or form a structure or device portion as described herein.

In the illustrated example, the system (600) includes one or more reaction chambers (602), a hafnium precursor source (603), a zirconium precursor source (604), an oxygen reactant source (605), a dopant precursor source (606), a purge gas source (608), an exhaust (610), and a controller (612). The reaction chamber (602) can include any suitable reaction chamber, such as an ALD reaction chamber.

The precursor sources (603, 604) can include a vessel and one or more precursors as described herein-alone or mixed with one or more carrier (e.g., inert) gases. The dopant precursor source (606) can include a vessel and one or more dopant compounds as described herein-alone or mixed with one or more carrier gases. The purge gas source (608) can include one or more inert gases such as N₂ or a noble gas, as described herein. The system (600) can include any suitable number of sources. The sources (603)-(608) can be coupled to reaction chamber (602) via lines (614)-(618), which can each include flow controllers, valves, heaters, and the like. The exhaust (610) can include one or more vacuum pumps.

The controller (612) includes electronic circuitry and software to selectively operate valves, manifolds, heaters, pumps and other components included in the system (600). Such circuitry and components operate to introduce precursors, reactants, and purge gases from the respective sources (604)-(608). The controller (612) can control timing of gas pulse sequences, temperature of the substrate and/or reaction chamber, pressure within the reaction chamber, and various other operations to provide proper operation of the system (600). The controller (612) can include control software to electrically or pneumatically control valves to control flow of precursors, reactants (i.e. nitrogen compounds and/or oxygen compounds) and purge gases into and out of the reaction chamber (602). The controller (612) can include modules such as a software or hardware component, e.g., a FPGA or ASIC, which performs certain tasks. A module can advantageously be configured to reside on the addressable storage medium of the control system and be configured to execute one or more processes.

Other configurations of the system (600) are possible, including different numbers and kinds of precursor and reactant sources and purge gas sources. Further, it will be appreciated that there are many arrangements of valves, conduits, precursor sources, and purge gas sources that may be used to accomplish the goal of selectively feeding precursors, reactants and/or gases into the reaction chamber (602). Further, as a schematic representation of a system, many components have been omitted for simplicity of illustration, and such components may include, for example, various valves, manifolds, purifiers, heaters, containers, vents, and/or bypasses.

During operation of the reactor system (600), substrates, such as semiconductor wafers (not illustrated), are transferred from, e.g., a substrate handling system to reaction chamber (602). Once substrate(s) are transferred to the reaction chamber (602), one or more gases from the gas sources (603)-(608), such as precursors, reactants, carrier gases, and/or purge gases, are introduced into reaction chamber (602).

It shall be understood that the following embodiments can apply to any one of the methods disclosed herein, irrespective of the precursor and/or reactant that is used in such methods, unless a corresponding embodiment would render the method in question unworkable.

In some embodiments, the HZO layer is deposited at a temperature of at least 100° C. to at most 500° C., or at a temperature of at least 150° C. to at most 450° C., or at a temperature of at least 250° C. to at most 350° C., or at a temperature of around 350° C.

In some embodiments, the precursor is provided to the reaction chamber from a precursor source maintained at a temperature of at least 25° C. to at most 200° C., or at a temperature of at least 50° C. to at most 150° C., or at a temperature of at least 75° C. to at most 125° C.

In some embodiments, the dopant compound is provided to the reaction chamber from a dopant source maintained at a temperature of at least 25° C. to at most 200° C., or at a temperature of at least 50° C. to at most 150° C., or at a temperature of at least 75° C. to at most 125° C.

In some embodiments, the oxygen compound is provided to the reaction chamber from an oxygen source maintained at a temperature of at least 25° C. to at most 200° C., or at a temperature of at least 50° C. to at most 150° C., or at a temperature of at least 75° C. to at most 125° C.

In some embodiments, the doped HZO layer is deposited at a pressure of at least 0.01 Torr to at most 100 Torr, or at a pressure of at least 0.1 Torr to at most 50 Torr, or at a pressure of at least 0.5 Torr to at most 25 Torr, or at a pressure of at least 1 Torr to at most 10 Torr, or at a pressure of at least 2 Torr to at most 5 Torr.

The doped HZO layer can be deposited in any suitable reactor. Thus, in some embodiments, the doped HZO layer is deposited in a cross-flow reactor. In some embodiments, the doped HZO layer is deposited in a showerhead reactor. In some embodiments, the doped HZO layer is deposited in a hot-wall reactor. Doing so can advantageously enhance uniformity and/or repeatability of doped HZO layer deposition processes.

In some embodiments, the substrate is subjected to an annealing step in an ambient comprising hydrogen and nitrogen after the cyclical deposition process. Suitably, the annealing step can be carried out at a temperature from at least 300° C. to at most 600° C. Alternatively, the annealing step can be carried out at a temperature from at least 300° C. to at most 1000° C.

In some embodiments, the precursor is provided to the reaction chamber from a temperature-controlled precursor vessel. In some embodiments, the temperature-controlled precursor vessel is configured for cooling the precursor. In some embodiments, the temperature-controlled precursor vessel is configured for heating the precursor. In some embodiments, the temperature controlled precursor vessel is maintained at a temperature of at least −50° C. to at most 20° C., or at a temperature of at least 20° C. to at most 250° C., or at a temperature of at least 100° C. to at most 200° C.

In some embodiments, the precursor is provided to the reaction chamber by means of a carrier gas. Exemplary carrier gasses include nitrogen (N₂) and a noble gas such as He, Ne, Ar, Xe, or Kr.

As an exemplary embodiment, the method as disclosed herein was performed using a system according to FIG. 6 as described herein. According to the embodiment, the precursor pulse comprises hafnium and zirconium and the dopant precursor pulse comprises Si, Al, or Ge. The following exemplary parameters were used during material deposition in the system (600):
Substrate temperature: 160° C.
Pressure in the reaction chamber: 8 Torr
precursor pulse (Hf and Zr): 100-150 ms
Purge time after precursor pulse: 40 000 ms
dopant pulse (Si, Al or Ge): 10 000 ms
Purge time after dopant pulse: 40 000 ms
Amount of cycles: 400

The subject matter of the present disclosure includes all novel and nonobvious combinations and sub-combinations of the various processes, systems, and configurations, and other features, functions, acts, and/or properties disclosed herein, as well as any and all equivalents thereof.

The illustrations presented herein are not meant to be actual views of any particular material, structure, or device, but are merely idealized representations that are used to describe embodiments of the disclosure.

The particular implementations shown and described are illustrative of the disclosure and its best mode and are not intended to otherwise limit the scope of the aspects and implementations in any way. Indeed, for the sake of brevity, conventional manufacturing, connection, preparation, and other functional aspects of the system may not be described in detail. Furthermore, the connecting lines shown in the various figures are intended to represent exemplary functional relationships and/or physical couplings between the various elements. Many alternative or additional functional relationships or physical connections may be present in the practical system, and/or may be absent in some embodiments.

It is to be understood that the configurations and/or approaches described herein are exemplary in nature, and that these specific embodiments or examples are not to be considered in a limiting sense, because numerous variations are possible. The specific routines or methods described herein may represent one or more of any number of processing strategies. Thus, the various acts illustrated may be performed in the sequence illustrated, in other sequences, or omitted in some cases.

1. A method for forming a doped hafnium zirconium oxide (HZO) layer on a substrate, the method comprising the steps of:
a) providing said substrate in a reaction chamber;
b) executing one or more cycles, a cycle comprising
i. a hafnium precursor pulse, wherein at least a part of the substrate is contacted with one or more hafnium precursor by introducing said one or more hafnium precursor in the reaction chamber;
ii. a zirconium precursor pulse, wherein at least a part of the substrate is contacted with one or more zirconium precursor by introducing said one or more zirconium precursor in the reaction chamber;
iii. an oxygen reactant pulse, wherein at least a part of the substrate is contacted with one or more oxygen reactant by introducing said one or more oxygen reactant in the reaction chamber; and
iv. a dopant precursor pulse, wherein at least a part of the substrate is contacted with one or more dopant precursor by introducing said one or more dopant precursor in the reaction chamber,
thereby forming a doped HZO layer;
wherein said dopant precursor comprises a dopant element characterized by having three or four valence electrons and an atomic radius which is less than the atomic radius of an Hf or Zr element of the HZO layer.

2. The method according to claim 1, wherein an oxygen reactant pulse is carried out after each hafnium precursor pulse and/or after each zirconium precursor pulse.

3. The method according to claim 2, wherein said dopant precursor pulse is carried out after said hafnium precursor pulse without any intervening oxygen reactant pulse.

4. The method according to claim 2, wherein said dopant precursor pulse is carried out after said zirconium precursor pulse without any intervening oxygen reactant pulse.

5. The method according to claim 1, wherein each pulse is followed by a purge with an inert gas chosen from at least one of N₂ and a noble gas.

6. The method according to claim 1, wherein said hafnium precursor pulse, said zirconium precursor pulse, said oxygen reactant pulse and/or said dopant precursor pulse comprises a plurality of micropulses.

7. The method according to claim 1, wherein said dopant element is selected from the list consisting of Aluminium, Silicon, Nickel, Germanium, Gallium and Carbon.

8. The method according to claim 1, wherein the concentration of said dopant element in said HZO layer ranges between 0.50 and 8.0% of the relative dopant element concentration, more particularly between 1.0 and 5.0% of the relative dopant element concentration, and even more particularly between 2.0 and 4.50% of the relative dopant element concentration.

9. The method according to claim 1, wherein said dopant element is Al.

10. The method according to claim 9, wherein said dopant precursor is a low-reactivity precursor, said dopant precursor preferably being a low-reactivity Aluminium precursor represented by the general formula Al(R′)₃, wherein each R¹ is independently selected from the group consisting of hydrogen, halogen, alkyl, alkenyl, N(R²)₂, cycloalkyl, and alkoxy, and wherein each R² is chosen from hydrogen, alkyl, or alkenyl.

11. The method according to claim 1, wherein said dopant element is Si.

12. The method according to claim 11, wherein said dopant precursor is a low-reactivity precursor, said dopant precursor preferably being a low-reactivity Silicon precursor selected from the list consisting of silicon tetraacetate (Si(OOCCH₃)₄), and Si(R³)₄, wherein each R³ is independently selected from the group consisting of hydrogen, halogen, alkyl, alkenyl, N(R⁴)₂, cycloalkyl, and alkoxy, and wherein each R⁴ is chosen from hydrogen, alkyl, or alkenyl.

13. The method according to claim 1, wherein said dopant element is Ge.

14. The method according to claim 13, wherein said dopant precursor is a low-reactivity precursor, said dopant precursor preferably being a low-reactivity Germanium precursor represented by the general formula Ge(R⁵)₄, wherein each R⁵ is independently selected from the group consisting of hydrogen, halogen, alkyl, alkenyl, N(R⁶)₂, cycloalkyl, and alkoxy, and wherein each R⁶ is chosen from hydrogen, alkyl, or alkenyl.

15. The method according to claim 1, wherein said hafnium precursor is chosen from the list consisting of HfCl₄, HfBr₄, HfI₄, Tetrakis(dimethylamido)hafnium (Hf(N(CH₃)₂)₄), Tetrakis(ethylmethylamino)hafnium (Hf(N(C₂H₅)(CH₃))₄), Tetrakis(diethylamido)hafnium (Hf(N(C₂H₅)₂)₄), Hf(OR)₄, Tris(dimethylamino)cyclopentadienyl Hafnium (HfCp(NMe₂)₃), Hf(CpMe)₂[OMe]Me, Hf(CpMe)₂Me₂, and Tetrakis(1-methoxy-2-methyl-2-propoxy)hafnium (Hf(mmp)₄).

16. The method according to claim 1, wherein said zirconium precursor is chosen from the list consisting of tetrakis(dimethylamino)zirconium, tetrakis(diethylamino)zirconium, and tetrakis(ethylmethylamino)zirconium, and Tris(dimethylamino)cyclopentadienyl Zirconium.

17. The method according to claim 1, wherein the decomposition temperature of the dopant precursor is higher compared to the operating temperature to form the doped hafnium zirconium oxide (HZO) layer.

18. The method according to claim 17, wherein the operating temperature to form the doped HZO layer is between 150° C. and 450° C., preferably between 250° C. and 350° C., more preferably around 300° C.

19. The method according to claim 1, wherein the method is an Atomic Layer Deposition (ALD) method.

20. The method according to claim 1, wherein the method further comprising the step of providing a seed layer prior to forming said doped HZO layer, said seed layer being a ZrO₂ seed layer.

21. The method according to claim 1, wherein said substrate comprises a Metal Oxide (MO) surface layer, and/or wherein said method further comprises the step of forming a Metal Oxide (MO) top layer on said doped HZO layer, thereby forming a layered doped HZO structure.

22. The method according to claim 21, wherein the MO surface layer and/or the MO top layer is in direct contact with the doped HZO layer.

23. The method according to claim 21, wherein said metal oxide is TiO₂.

24. The method according to claim 1, wherein said doped HZO layer stabilises the tetragonal phase of said HZO layer such that a Morphotropic Phase Boundary (MPB) is reached between the orthorhombic and tetragonal phases of said HZO layer to allow a change in the polarization switching voltage of said HZO layer.

25. The method according to claim 24, wherein changing the polarization switching voltage of said HZO layer changes the Capacitance Voltage (CV) linearity of said HZO layer.

26. The method according to claim 1, wherein said doped HZO layer increases the dielectric constant value (κ) of said HZO layer.

27. The method according to claim 26, wherein the dielectric constant value (κ) of said doped HZO layer is above 35 at about −2 and −3 MV/cm.

28. The method according to claim 1, wherein said doped HZO layer is formed without any intervening vacuum break.

29. The method according to claim 21, wherein said layered doped HZO structure is formed without any intervening vacuum break.

30. A doped hafnium zirconium oxide (HZO) layer, obtained by the method according to claim 1.

31. A layered doped HZO structure, obtained by the method according to claim 21.

32. Use of a doped hafnium zirconium oxide (HZO) layer obtained by the method according to claim 1 as an insulator in a metal-insulator-metal capacitor (MIM CAPS).
